(19) United States
(12) Patent Application Publication
(10) Pub. No.: US 2008/0261392 A1
(43) Pub. Date: Oct. 23, 2008

(54) CONDUCTIVE VIA FORMATION

(76) Inventor: John Trezza, Nashua, NH (US)

Correspondence Address: FOLEY & LARDNER LLP, 150 EAST GILMAN STREET, P.O. BOX 1497, MADISON, WI, 53701-1497, US

(21) Appl. No.: 11/738,748

(22) Filed: Apr. 23, 2007

(51) Int. Cl. H01L 21/4763

(52) U.S. Cl. 438/637; 257/E21.495

(57) ABSTRACT

A method involves depositing a first electrically conductive material, using a deposition technique, into a via formed in a material, the via having a diameter at a surface of the material of less than about 10 μm and a depth of greater than about 50 μm, so as to form a seed layer within the via, then creating a thickening layer on top of the seed layer by electrolessly plating the seed layer with a second electrically conductive material without performing any activation process within the via between via formation and the creating the thickening layer, and then electroplating a conductor metal onto the thickening layer until a volume bounded by the thickening layer within the via is filled with the conductor metal.

### FIELD OF THE INVENTION

The present invention relates to semiconductors and, more particularly, to electrically conductive paths for such devices.

### BACKGROUND

When making electrically conductive vias, the deeper the vias are, the more difficult it is to make their entire length electrically conductive, particularly where the width of the via opening is much narrower than its depth (i.e. the aspect ratio is high). Moreover, if the via needs to be insulated to isolate the internal metal from the surrounding semiconductor material, the aspect ratio will be even higher. Thus, when depositing a seed layer in a high aspect ratio via of a semiconductor, it is not uncommon for the area near the bottom of the via to only have a very thin layer of seed material and, in some instances, not have any at all. This problem can begin to become acute when the absolute depth of the via is greater than 75 μm; above 125 μm it becomes extremely challenging.

As the fill process begins, initial insertion of the wafer into the electroplating bath results in the chemicals of the electroplating bath initially etching away the at the seed layer before the actual electroplating deposition can begin. Where the seed layer is very thin, this initial etching action of the electroplating bath can actually eliminate part or all the entire seed near the bottom of the via. Where part of the seed layer is removed, the result would be micro-void formation at the bottom of the via. FIG. 1 is an enlarged photograph of a cross section of a semiconductor wafer with a set of vias having micro-voids. Where all of the seed is removed (or none was deposited because of the high aspect ratio), with or without large absolute depth, the result would be complete void formation at the bottom of the via. FIG. 2 is a photograph of a cross section of a semiconductor wafer with a set of vias having complete voids.

If there are micro- or complete voids in the seed layer, but the underlying diffusion barrier material is conductive then, during electroplating, certain areas (i.e. those coated with seed) will plate while other areas may not. The result is that the plated areas trap the non-plated areas. This is visble in FIG. 1, for example, where seed was deposited on the very bottom of the vias (because they face the opening at the top of the via, but no seed on the sides of the vias nearest the bottom. As a result, after electroplating, there are regions where electroplating occurred at the bottom of the vias and higher up on the sides, but not on the sides near the bottoms of the vias. This action occurred because there was conductivity through the underlying diffusion barrier material to the very bottom copper seed layers for electroplating, but on regions above, there was either no seed layer or a thin seed layer that was etched away upon insertion into the electroplating bath. In either case, the result is unsatisfactory.

Thus, there is a need for an approach that does not result in creation of undesirable micro-voids or voids.

### SUMMARY OF THE INVENTION

We have developed a way to create electrically conductive, high aspect ratio vias that ensure that the deposited seed has enough thickness to ensure that any etching that occurs during initial insertion into an electroplating bath does not create an area of no seed layers.

We have further developed a way to create electrically conductive, high aspect ratio vias that ensures that, if there are voids in the deposited seed layer, they are “patched” prior to electroplating so that micro-voids do not form.

Moreover, we have developed a way to do either or both of the above without activation of a diffusion barrier layer or an insulator (e.g. dielectric) layer.

In overview, one aspect of our technique involves first depositing a first electrically conductive material as a seed layer, using a deposition technique, into a via formed in a material. Then, creating a thickening layer on top of the seed layer by electrolessly plating the seed layer without performing any activation process within the via between via formation and creating the thickening layer. Then, electroplating a conductor metal onto the thickening layer until a volume bounded by the thickening layer within the via is filled with the conductor metal.

The advantages and features described herein are a few of the many advantages and features available from representative embodiments and are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

FIG. 1 is a photograph of a cross section of a semiconductor wafer with a set of vias having micro-voids;

FIG. 2 is a photograph of a cross section of a semiconductor wafer with a set of vias having complete voids;

FIGS. 3A, 3B and 3C each illustrate, in overly simplified form, high aspect ratio vias;

FIG. 4A illustrates, in overly simplified form, the high aspect ratio via after the insulator of this optional step has been applied to the inner surfaces of the via.

FIGS. 4B and 4C are identical to FIGS. 3A through 3C;

FIG. 5A illustrates, in overly simplified form, the high aspect ratio via after the optional diffusion barrier has been deposited on the insulator of the via of FIG. 4A using sputter deposition;

FIG. 5B illustrates, in overly simplified form, the high aspect ratio via after the optional diffusion barrier has been deposited on the inner surfaces of the via of FIG. 4B using sputter deposition;

FIG. 5C is identical to FIGS. 3C and 4C;

FIG. 6A through FIG. 6C illustrate, in overly simplified form, the high aspect ratio via after the seed layer has been deposited on the respective inner surfaces within the via using a deposition process;

FIG. 7A through FIG. 7C illustrate, in overly simplified form, the high aspect ratio via after the thickening layer has been electrolessly plated on the respective seed layers; and

FIG. 8A through 8C illustrate, in overly simplified form, the high aspect ratio via after electroplating is complete.

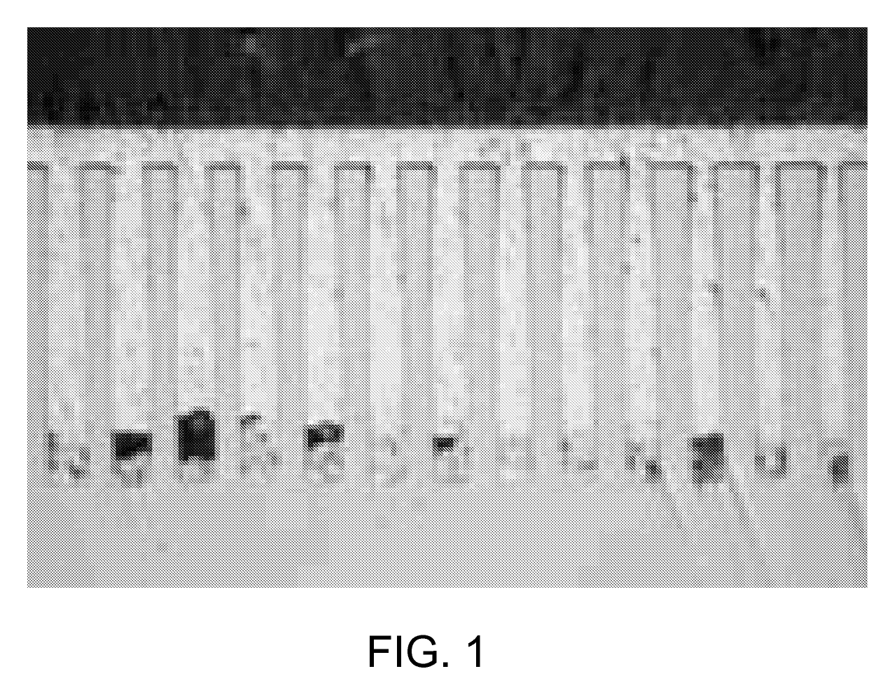

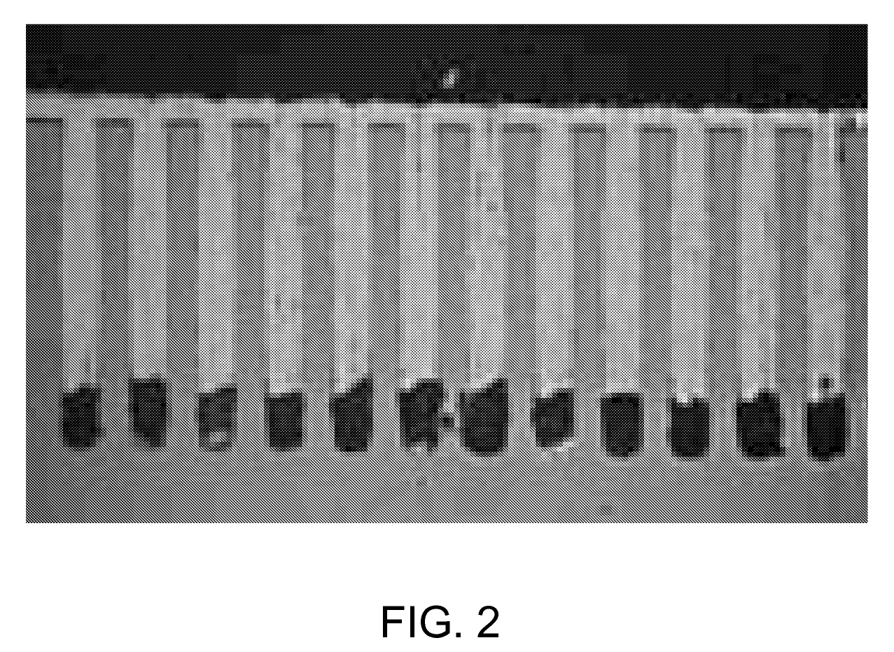

### DETAILED DESCRIPTION

U.S. patent applications Ser. Nos. 11/329,481, 11/329,506, 11/329,539, 11/329,540, 11/329,556, 11/329,557, 11/329,558, 11/329,574, 11/329,575, 11/329,576, 11/329,873, 11/329,874, 11/329,875, 11/329,883, 11/329,885, 11/329,886, 11/329,887, 11/329,952, 11/329,953, 11/329,955, 11/330,011 and 11/422,551, incorporated herein by reference, describe various techniques for forming small, deep vias in, and electrical contacts for, semiconductor wafers. Our techniques allow for creation of electrically conductive vias at densities and placements previously unachievable on a chip, die or wafer scale.

With our technique, as described below, we can create electrically conductive high aspect ratio vias that are between about 10 to about 20 times or more deeper than they are wide (i.e. a 10:1 to 20:1 or more aspect ratio).

Advantageously, our approach is versatile in that it can be used for vias that are as small as 4 μm in diameter or smaller, although the typical diameter range will be 15 μm or less, in some cases 7 μm or less, and in still other cases 5 μm or less, and typically, of between 50 μm deep and about 130 μm deep (for diameters of between about 4 μm and about 5 μm), of between 50 μm deep and about 130 μm deep. Table 1 below illustrates the expected typical range combinations where the approach will be most beneficial:

TABLE 1

Via Depth Range

| Via | Typical | |
|---|---|---|
| Diameter | Min | Typical Max |
| 15 μm | 75 μm | 130 μm or more |
| 10 μm | 75 μm | 130 μm or more |
| 7 μm | 50 μm | 130 μm or more |
| 5 μm | 50 μm | 130 μm or more |
| 4 μm | 50 μm | 130 μm or more |

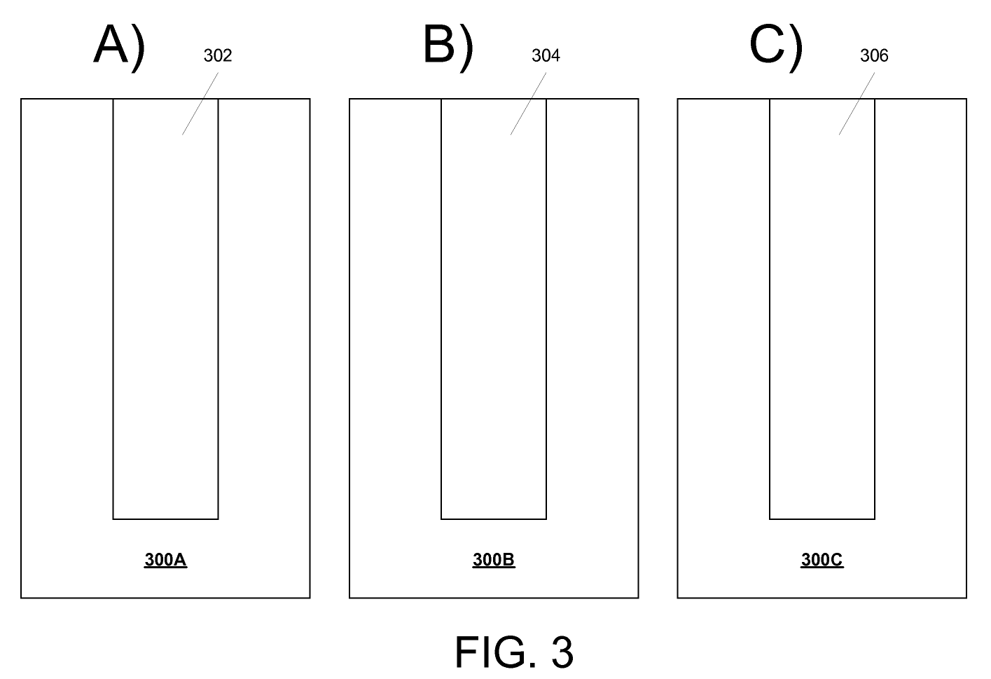

The approach will now be described with reference to FIG. 3 through FIG. 8 in connection with a semiconductor. Note, however, that the approaches described herein are not confined to semiconductors, but can also be straightforwardly used on other materials, such as ceramics, dielectrics, polymers, etc.

FIGS. 3A, 3B and 3C each illustrate, in overly simplified form, high aspect ratio vias 302, 304, 306 of the typical dimensions noted in Table 1 formed in, for example, three different pieces 300A, 300B, 300C of semiconductor material, using any of the approaches described in the above-incorporated applications or other approaches such as laser drilling. This is the starting point for the technique.

Optionally, in cases where a semiconductor material is used and the conductor in the via should not be shorted to that semiconductor material, the approach begins by coating the inner surfaces of the via with a thin layer of insulator or dielectric material.

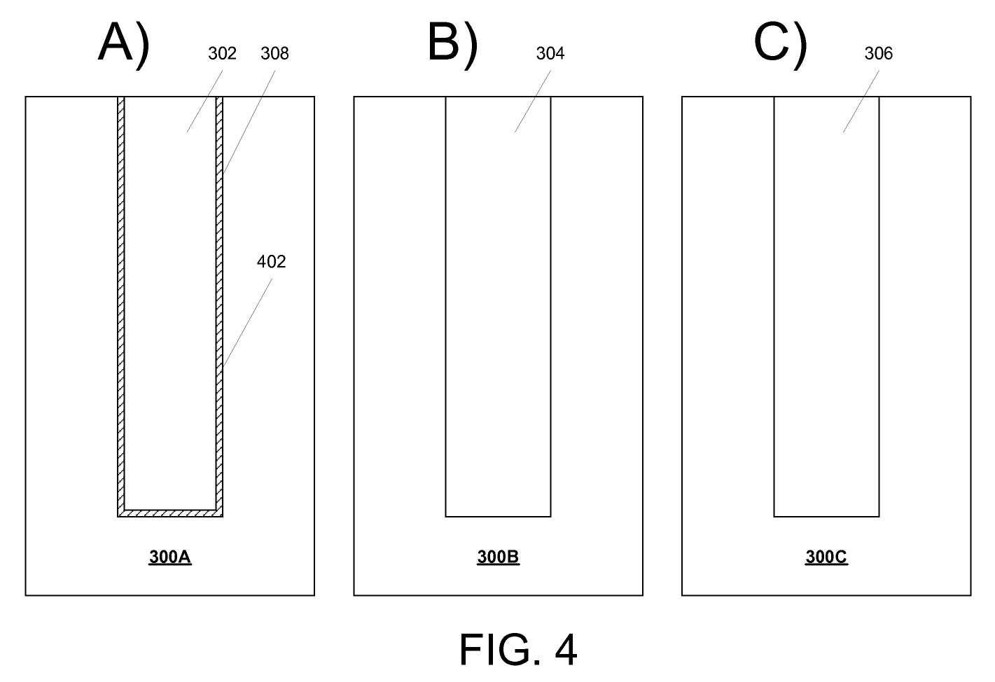

FIG. 4A illustrates, in overly simplified form, the high aspect ratio via 300A after the insulator 402 of this optional step has been applied to the inner surface 308 of the via. FIGS. 4B and 4C are identical to FIGS. 3A through 3C because their variants do not involve use of this optional processing step.

Optionally, next, a diffusion barrier 500 (if desired or necessary) is applied by deposition on top of the insulator 402 (if present) or the inner surface 308 (if no insulator is present).

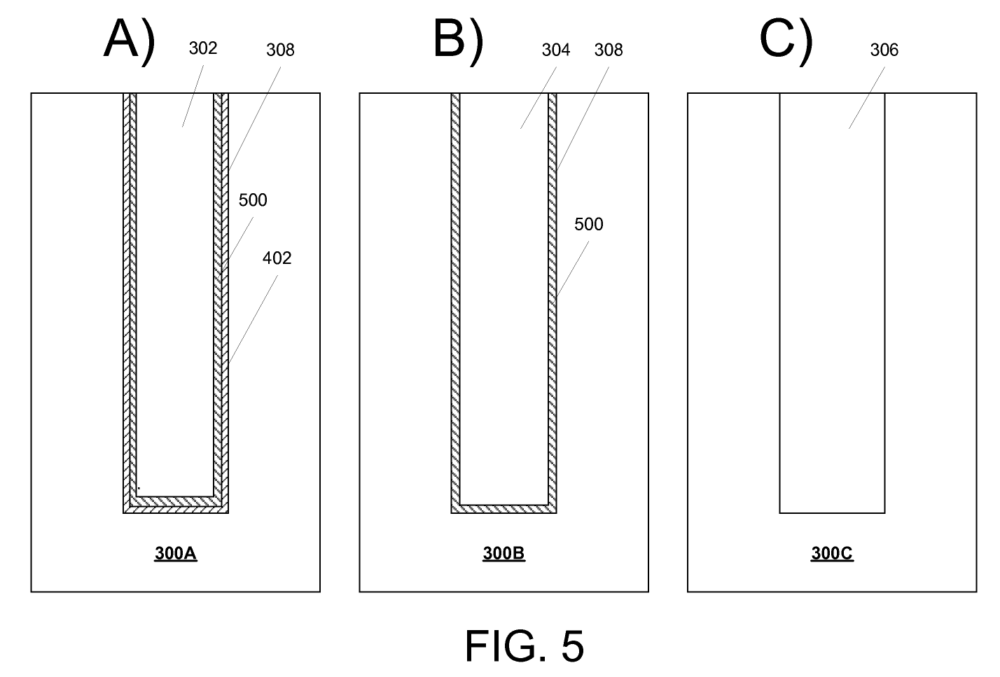

FIG. 5A illustrates, in overly simplified form, the high aspect ratio via after the optional diffusion barrier 500 has been deposited on the insulator 402 of the via of FIG. 4A using sputter deposition.

FIG. 5B illustrates, in overly simplified form, the high aspect ratio via after the optional diffusion barrier 500 has been deposited on the inner surface 308 of the via of FIG. 4B using sputter deposition. Mote that, in some variants, due to for example the depth, the diffusion barrier 500 could have a distribution similar to what could happen with the seed layer (e.g. discontinuities, thinness, etc.). However, those types of discontinuities in the diffusion barrier 500 are not important, nor is thickness or strength, as long as the subsequent steps can connect the diffusion barrier 500 to the bottom of the via.

FIG. 5C is identical to FIGS. 3C and 4C because this variant does not involve use of this optional processing step.

Next, a seed layer 602, 604, 606 is applied on top of the optional diffusion barrier 500 of FIG. 5A and FIG. 5B or on the inner surface 308 of the via of FIG. 5C, depending upon which, if any, of the two preceding optional steps have been used. Depending upon the particular variant, the seed layer could be made up of, for example, gold, tungsten, nickel, aluminum, or an alloy of gold, tungsten, nickel or aluminum, to name a few.

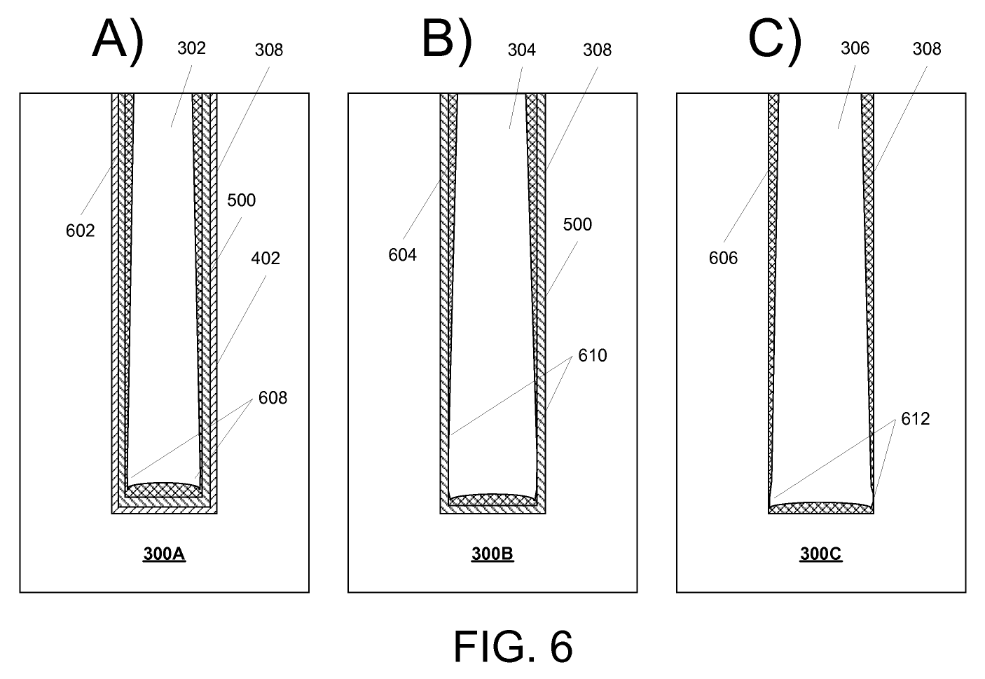

FIG. 6A through FIG. 6C illustrate, in overly simplified form, the high aspect ratio via after the seed layer 602, 604, 606 has been deposited on the respective inner surfaces 308 within the via using a deposition process, for example, sputter deposition, physical vapor deposition, chemical vapor deposition, evaporative deposition or other metal deposition process. Note that seed layer 602 of the via of FIG. 6A is an extremely thin in an area 608 near the bottom of the via which is so thin that it would be removed by initial insertion into an electroplating bath, the seed layer 604 of the via of FIG. 6B stops at a point 610 above the bottom of the via so that it does not even reach the bottom of the via, and the via of FIG. 6C has a seed layer 606 that, although there is some continuous coverage of seed layer 606 down to and including the via bottom, there are also some discontinuities 612 or gaps in seed layer coverage near the bottom of the via. Note that the diagrams are not meant to imply that a particular result in seed deposition has any relation to, or is dependent upon, variant(s) involving use of an insulator and/or barrier material. The particular result in seed deposition is solely related to the seed deposition itself, not the material underlying it.

Advantageously, although the application of the seed layer is intended to coat all of the surfaces without interruption, as will be seen, it does not matter if the seed layer is actually very thin near the lowermost part of the via or even if there is a discontinuity between the seed layer hear the bottom of the via and the actual via bottom. As presently contemplated, the seed layer is copper, although other metals, such as gold, tungsten, or even alloys can be used.

Next, a thickening layer 702, 704, 706 is created on top of the seed layer by electrolessly plating the seed layer with the same material or, in the case of an alloy, a suitable component of the material that serves as the seed layer. Thus, it should now be understood that any metal or alloy can serve as the thickening or seed layers provided that the metal or alloy used as the seed layer is one that can be plated by the metal or alloy that will serve as the thickening layer using an electroless plating process without performing an activation process on the interior of the via between the time the via is created and completion of creation of the thickening layer.

The electroless plating is performed in a controlled manner, using known techniques suitable for the particular material, until the thickening layer is at least about 50 nanometers (“nm”) thick, but typically greater than 250 nm, and, in some variants, as thick as about the width of the gaps in the underlying deposited seed layer. In other words, the range will ideally be between about 50 nm and about the thickness of the widest gap in seed span, the upper point being one of practical convenience rather than limitation. By doing so, this thickening layer advantageously builds up thin areas of seed, allows discontinuities or gaps in the seed layer to be “bridged” by “shorting” across them, or both. In this way the metal in the via will be thick enough throughout so that initial insertion of the wafer into the electroplating bath will not etch away all of the metal in some area of the via and it will ensure that there is a continuous coating within the via that the electroplating, which will occur on top of the thickening layer, does not trap or create voids in the via.

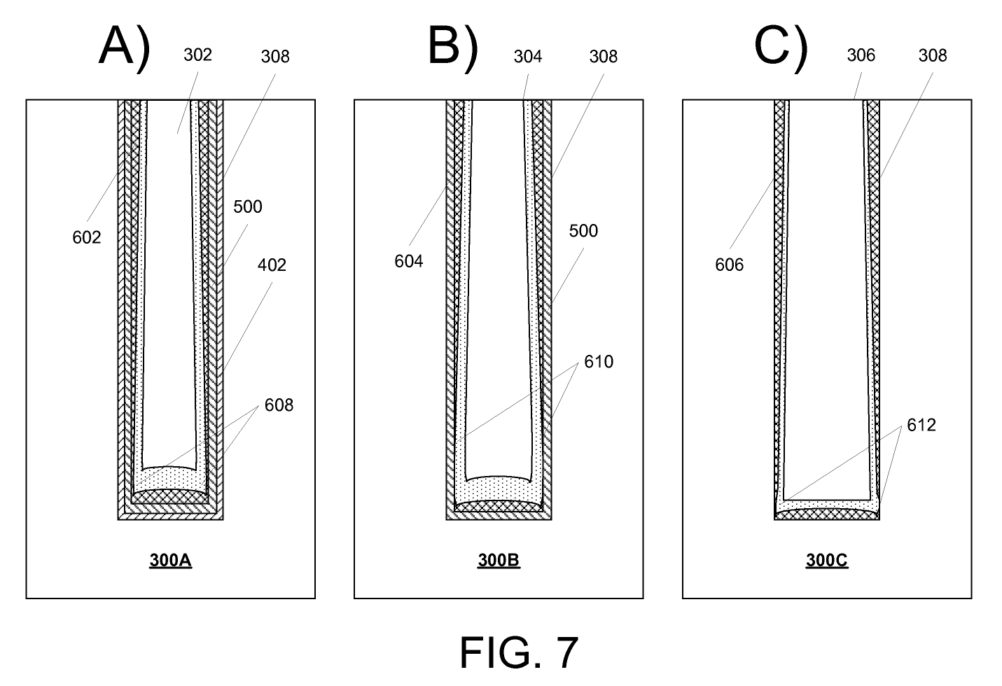

FIG. 7A through FIG. 7C illustrate, in overly simplified form, the high aspect ratio via after the thickening layer 702, 704, 706 has been electrolessly plated on the respective seed layers.

Note that, in FIG. 7A, the extremely thin area 610 of seed layer near the bottom of the via is now sufficiently thick so that it will not be removed by initial insertion of the wafer into the electroplating bath. Similarly, in FIG. 7B, the seed layer 610 stopped short of the bottom of the via has been connected to the seed layer from the bottom. In addition, in FIG. 7C, the discontinuities or gaps 612 in the seed layer no longer exist because they have been bridged.

Finally, the respective wafers containing the vias shown in FIG. 7A through 7C are inserted into an electroplating bath and electroplated until the vias are each filled with conductor 800.

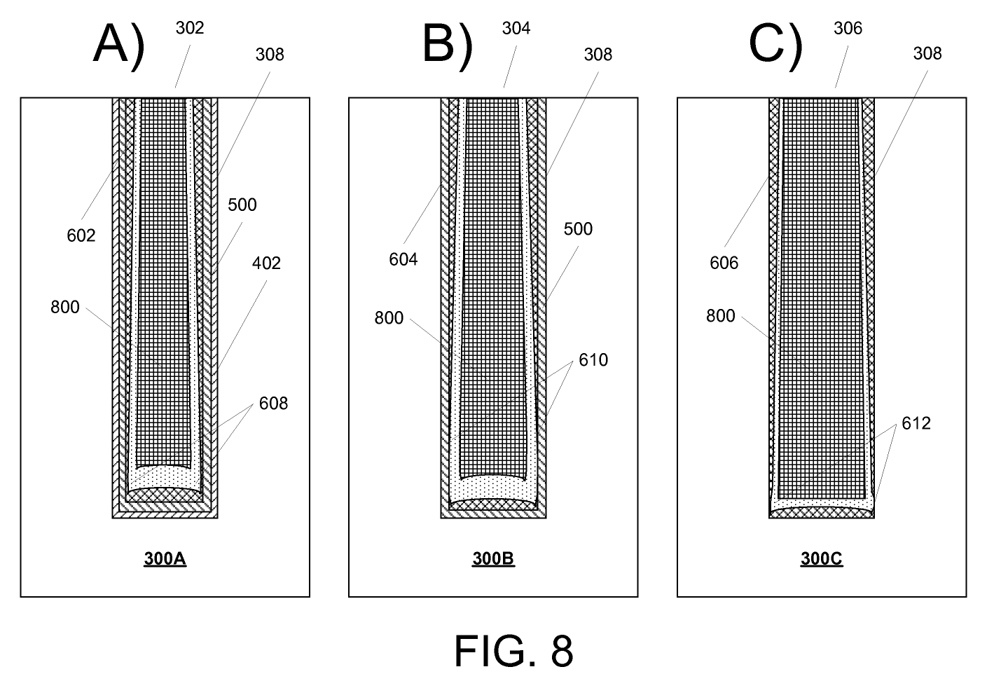

FIGS. 8A through 8C illustrate, in overly simplified form, the high aspect ratio via after electroplating is complete. At this point, the vias 302, 304, 306 are filled with conductor 800 and, depending upon the particular application, further processing can be performed on the wafer as needed or desired, for example, thinning or creation of a contact such as described in the above-incorporated applications.

Note that, advantageously, the above was performed without any activation of the insulator or diffusion barrier or similar such process, such as would be required if one were to try to electrolessly or electro-plate directly to the insulator or diffusion barrier surfaces.

It should thus be understood that this description (including the figures) is only representative of some illustrative embodiments. For the convenience of the reader, the above description has focused on a representative sample of all possible embodiments, a sample that teaches the principles of the invention. The description has not attempted to exhaustively enumerate all possible variations. That alternate embodiments may not have been presented for a specific portion of the invention, or that further undescribed alternate embodiments may be available for a portion, is not to be considered a disclaimer of those alternate embodiments. One of ordinary skill will appreciate that many of those undescribed embodiments incorporate the same principles of the invention and others are equivalent.

What is claimed is:

1. A method, performed in sequence, the method comprising:
a) depositing a first electrically conductive material, using a deposition technique, into a via formed in a material, the via having a diameter at a surface of the material of less than about 15 μm and a depth of greater than about 50 μm, so as to form a seed layer within the via;
b) then creating a thickening layer on top of the seed layer by electrolessly plating the seed layer with a second electrically conductive material without performing any activation process within the via between via formation and the creating the thickening layer; and
c) then electroplating a conductor metal onto the thickening layer until a volume bounded by the thickening layer within the via is filled with the conductor metal.

2. The method of claim 1, wherein the first and second electrically conductive materials are both the same.

3. The method of claim 1, wherein the first electrically conductive material is an alloy and the second electrically conductive material is a component of the alloy.

4. The method of claim 1, wherein the second electrically conductive material is an alloy and the first electrically conductive material is a component of the alloy.

5. The method of claim 1, further comprising:
prior to performing a), depositing an insulator material onto an inner surface of the via.

6. The method of claim 5, wherein:
the creating the thickening layer is performed until the thickening layer is at least about 50 nm thick.

7. The method of claim 6, further comprising:
prior to performing a), depositing a diffusion barrier material onto the insulator material.

8. The method of claim 7, wherein:
the creating the thickening layer is performed until the thickening layer is at least about 50 nm thick.

9. The method of claim 1, further comprising:
prior to performing a), depositing a diffusion barrier material onto an inner surface of the via.

10. The method of claim 1, wherein the creating the thickening layer is performed until the thickening layer is at least about 50 nm thick.

11. The method of claim 1, wherein the seed layer comprises copper.

12. The method of claim 1, wherein the seed layer comprises at least one of:
gold, tungsten, nickel, aluminum, an alloy of gold, tungsten, nickel or aluminum.

13. The method of claim 1, wherein the diameter at a surface of the material is less than about 7 μm.

14. The method of claim 13, wherein the diameter at a surface of the material is less than about 5 μm.

15. The method of claim 13, wherein the diameter at a surface of the material is less than about 4 μm.

16. The method of claim 1, wherein the depth of the via is greater than about 75 μm.

17. The method of claim 16, wherein the depth of the via is greater than about 130 μm.

18. The method of claim 1, wherein the via has an aspect ratio of about 10:1 or more.

19. The method of claim 18 wherein the aspect ratio is between about 10:1 and about 20:1.

20. The method of claim 1, wherein the via has an aspect ratio of about 20:1 or more.
